(19) United States
(12) Patent Application Publication
(10) Pub. No.: US 2016/0043345 A1
(43) Pub. Date: Feb. 11, 2016

(54) LIGHT-EMITTING DEVICE

(71) Applicant: CANON KABUSHIKI KAISHA, Tokyo (JP)

(72) Inventors: Tatsuhito Goden, Machida-shi (JP); Takashi Moriyama, Yokohama-shi (JP)

(21) Appl. No.: 14/810,616

(22) Filed: Jul. 28, 2015

(30) Foreign Application Priority Data
Aug. 11, 2014 (JP) 2014-163371
Jun. 29, 2015 (JP) 2015-129570

(51) Int. Cl. H01L 51/52; H01L 27/32

(52) U.S. Cl. CPC H01L 51/5253; H01L 51/5206; H01L 51/5221; H01L 27/3246; H01L 27/3262; H01L 27/3276; H01L 51/5237; H01L 51/524; H01L 51/5259; H01L 27/3227

(57) ABSTRACT

The present invention provides a light-emitting device capable of effectively suppressing characteristic deterioration of an organic EL element caused by water. The light-emitting device includes a plurality of pixels arranged on a long substrate along a longitudinal direction of the substrate, each pixel including a light-emitting element including a lower electrode, an organic compound layer, and an upper electrode in a stated order from the substrate, a partition layer arranged between the lower electrode and the organic compound layer of the light-emitting element, having an opening which defines a light-emitting region of the light-emitting element, and made of an inorganic material, and a planarization layer arranged above the partition layer space from the organic compound layer, and made of a resin material.

### BACKGROUND OF THE INVENTION

1. Field of the Invention

The present invention relates to a light-emitting device and a method of manufacturing the same and, more particularly, to a light-emitting device using an organic electroluminescence element and a method of manufacturing the same. 2. Description of the Related Art

Laser scanning type printers based on the electrophotographic technology have widely spread. In a general laser beam printer, a photosensitive member is exposed by scanning light emitted from a laser light source by using a scanning unit. However, the structure of the laser scanning unit makes it difficult to decrease the device size.

On the other hand, a laser beam printer in which light-emitting elements are arranged in line and used as a light source for exposing a photosensitive member by controlling light emission thereof is being studied. Since the light source unit can be downsized, this system is useful to downsize the printer device. In particular, an organic electroluminescence element (to be referred to as “an organic EL element” hereinafter) is a high-resolution, low-power-consumption, light-emitting element, and suitable as a light-emitting element for the light source unit of the printer device.

The organic EL element is an excellent light-emitting element, but deteriorates the characteristics due to water. To maintain the light emission performance of the organic EL element, therefore, it is important to suppress the movement of water to the light-emitting element.

Japanese Patent Application Laid-Open No. 2009-021164 discloses a phenomenon in which water having entered from a pinhole formed in an electrode diffuses to a partition layer which partitions light-emitting regions of the organic EL elements and is made of a resin material, and deteriorates the light emission characteristics of the organic EL element, and a technique of suppressing this phenomenon. More specifically, Japanese Patent Application Laid-Open No. 2009-021164 proposes a method of suppressing the movement of water by forming a trench between a support member where a pinhole is to be formed and the partition layer. Note that Japanese Patent Application Laid-Open No. 2009-021164 discloses a hollow sealing technique using a sealing substrate as a sealing form of the organic EL element.

Unfortunately, the inventors of the present invention have found by examination that a slight amount of water is inherent in the partition layer made of a resin material, and this water sometimes moves to the organic EL element and deteriorates the element. Also, when performing a sealing form using film sealing, the direct movement of water from an external ambient to the partition through a defective portion of the sealing is not negligible. This water sometimes moves in the resin material and deteriorates the element.

### SUMMARY OF THE INVENTION

An object of the present invention is to provide a light-emitting device capable of effectively suppressing characteristic deterioration of an organic EL element caused by water, and a method of manufacturing the same.

According to an aspect of the present invention, there is provided a light-emitting device including a plurality of pixels arranged on a long substrate along a longitudinal direction of the substrate, each pixel including a light-emitting element including a lower electrode, an organic compound layer, and an upper electrode in an stated order named from the substrate, a partition layer arranged between the lower electrode and the organic compound layer of the light-emitting element, having an opening which defines a light-emitting region of the light-emitting element, and made of an inorganic material, and a planarization layer arranged above the partition layer spaced from the organic compound layer, and made of a resin material.

Further features of the present invention will become apparent from the following description of exemplary embodiments with reference to the attached drawings.

### BRIEF DESCRIPTION OF THE DRAWINGS

FIGS. 1 and 2 are plan views illustrating a structure of a light-emitting device according to a first embodiment of the present invention.

FIG. 3 is a schematic cross-sectional view illustrating the structure of the light-emitting device according to the first embodiment of the present invention.

FIGS. 4A, 4B, 5A and 5B are cross-sectional views illustrating a method of manufacturing the light-emitting device according to the first embodiment of the present invention.

FIG. 6 is a schematic cross-sectional view illustrating a structure of a light-emitting device according to a second embodiment of the present invention.

FIG. 7 is a view illustrating an arrangement of an image forming apparatus according to a third embodiment of the present invention.

### DESCRIPTION OF THE EMBODIMENTS

Preferred embodiments of the present invention will now be described in detail in accordance with the accompanying drawings. Well-known or publicly known techniques of this field of art are applicable to portions not particularly shown or described in this specification.

### First Embodiment

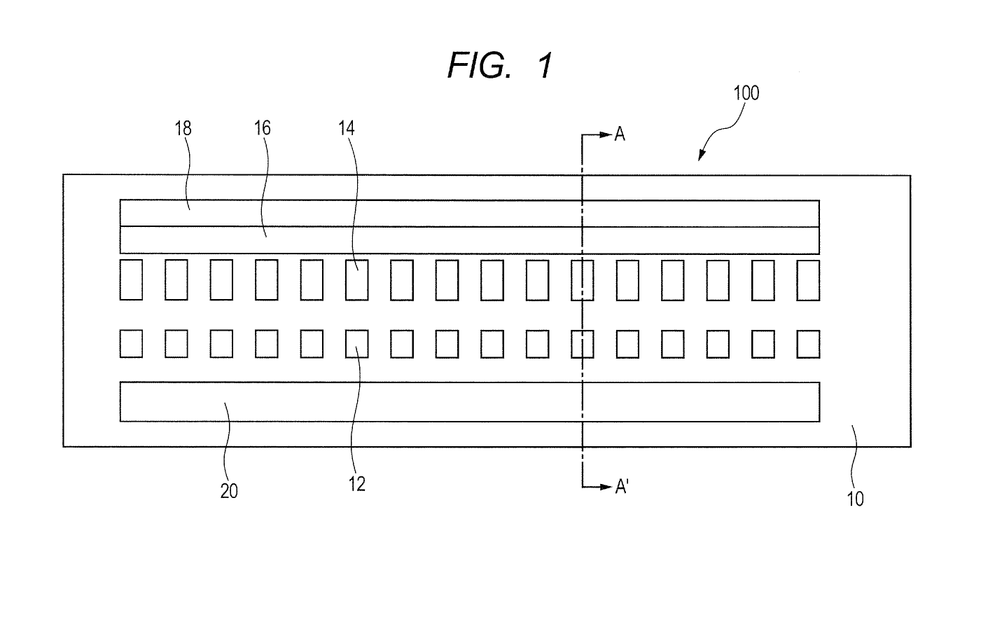

A light-emitting device and a method of manufacturing the same according to a first embodiment of the present invention will be explained with reference to FIGS. 1 to 5B.

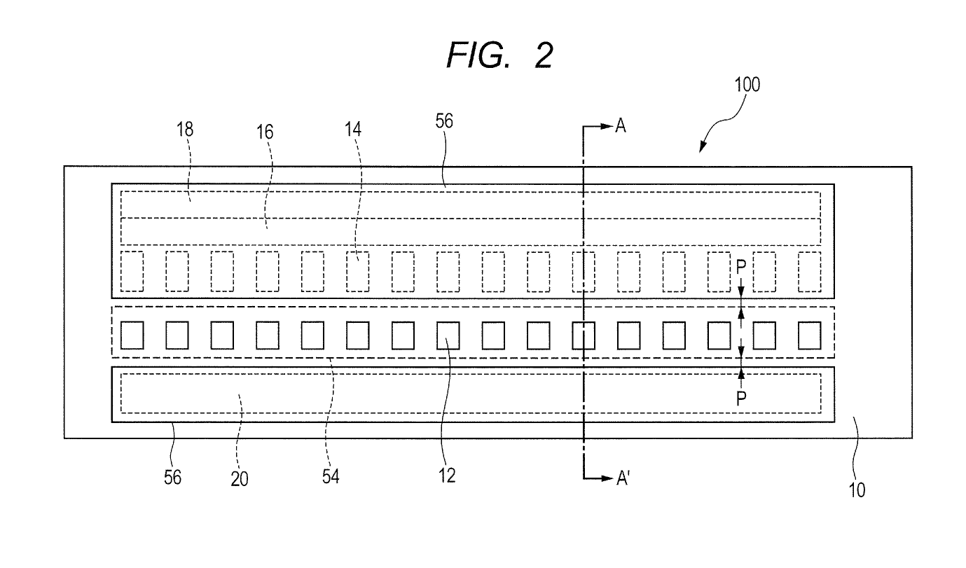

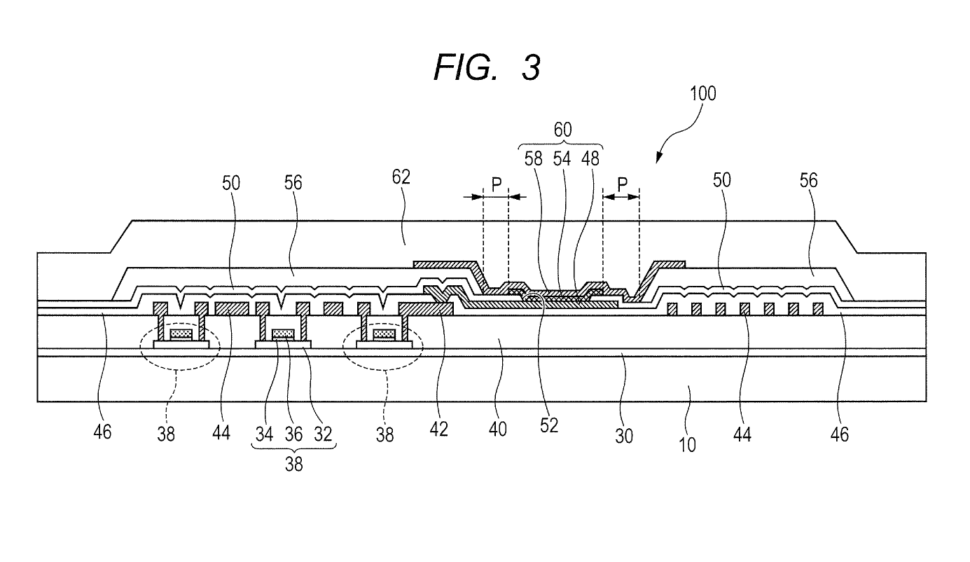

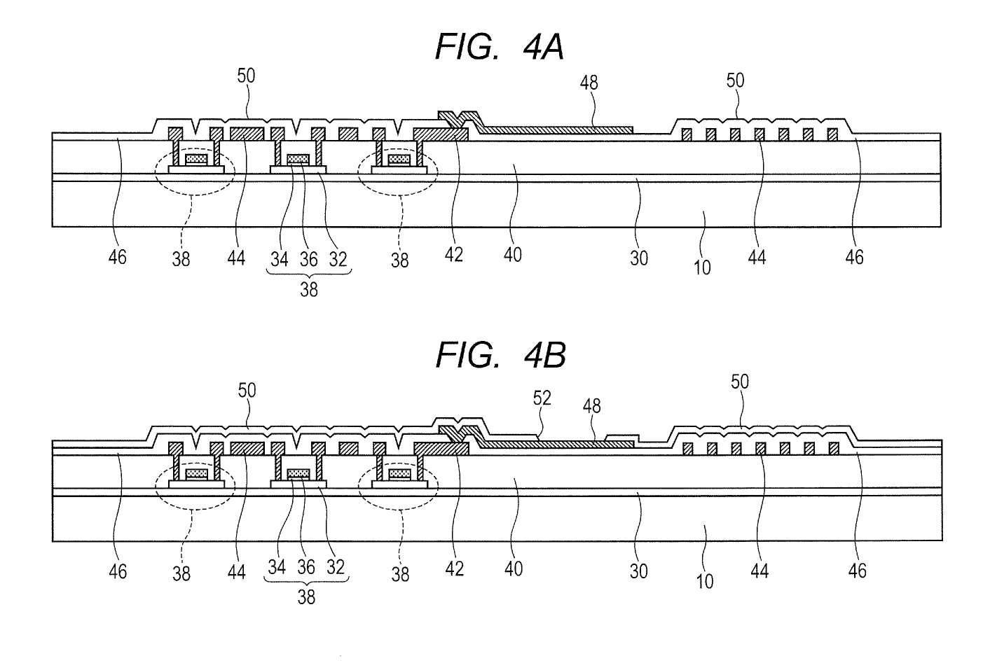

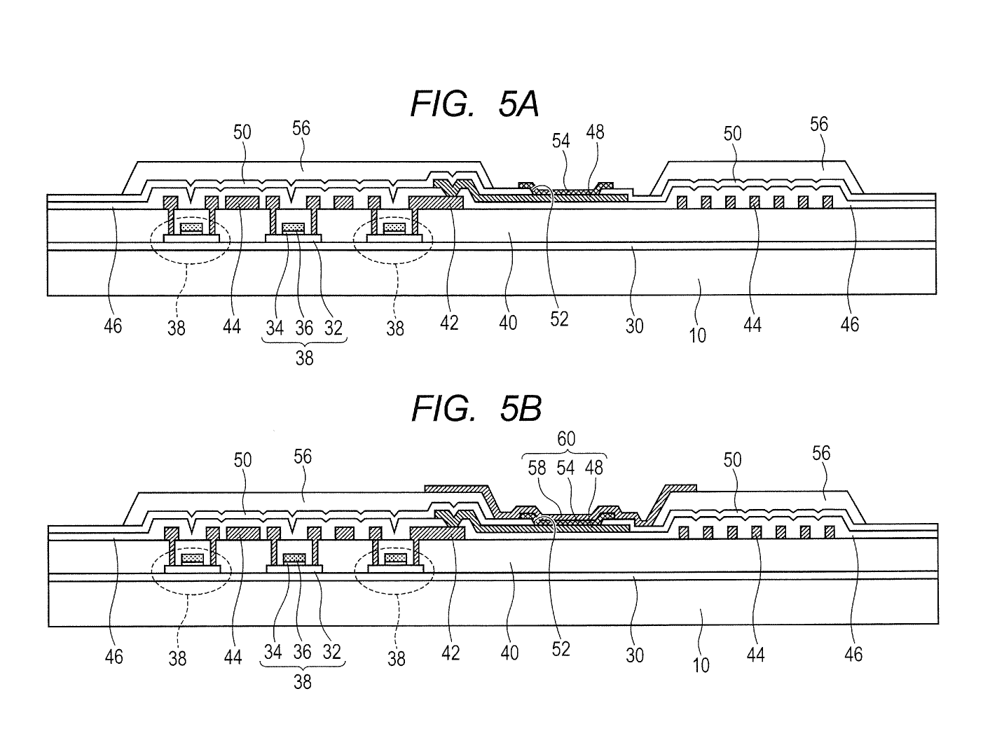

FIGS. 1 and 2 are plan views illustrating a structure of the light-emitting device according to the present embodiment. FIG. 3 is a schematic cross-sectional view illustrating the structure of the light-emitting device according to the present embodiment. FIGS. 4A to 5B are cross-sectional views illustrating a method of manufacturing the light-emitting device according to the present embodiment.

First, the structure of the light-emitting device according to the present embodiment will be explained with reference to FIGS. 1 to 3.

As illustrated in FIG. 1, a light-emitting device 100 according to the present embodiment includes a plurality of pixels 12, a plurality of pixel circuits 14, a power source line 16, a scanning circuit 18, and data lines 20 arranged on a substrate 10.

The pixels 12 are formed of an organic EL element. The plurality of pixels 12 are arranged in a row on the elongated substrate 10 along the longitudinal direction of the substrate 10. FIG. 1 exemplifies the pixels 12 arranged in one row for the sake of simplicity, but the pixels 12 may also be arranged in two or more rows. It is also possible to arrange the plurality of pixels 12 in a zigzag manner along the row direction. Furthermore, FIG. 1 illustrates sixteen pixels 12 arranged in the row direction for the sake of simplicity, but the number of pixels 12 to be arranged in the row direction is not limited to this. The number of pixels 12 to be arranged in the row direction can appropriately be determined in accordance with the width or resolution of an image to be exposed.

The pixel circuits 14 are arranged in a row adjacent and parallel to the row of the pixels 12 on the substrate 10. The pixel circuits 14 are circuits for controlling drive currents of the pixels 12, and are arranged in one-to-one correspondence with the pixels 12. Each pixel circuit is placed adjacent to the pixel in the widthwise direction of the substrate.

The power source line 16 and the scanning circuit 18 are arranged adjacent to the row of the pixel circuits on the substrate 10. The data lines 20 are arranged adjacent to the pixels 12 in the widthwise direction of the substrate. The pixel circuits 14, power source line 16, scanning circuit 18, and data lines 20 form a driving circuit for driving the plurality of pixels 12. The pixel circuits 14 and scanning circuit 18 are formed by switching elements such as a thin-film transistor, or a metal interconnection of aluminum, molybdenum, or the like. The power source line 16 and data lines 20 are also formed by a similar metal interconnection.

In a light-emitting device in which a plurality of pixels 12 are arranged in a row such as the light-emitting device 100 according to the present embodiment, it is difficult to arrange driving circuits for driving the pixels 12 on four sides around the pixel region. As illustrated in FIG. 1, therefore, the driving circuits are arranged on two sides sandwiching the row of the pixels 12. That is, the pixel circuits, pixels, and data lines are arranged in this order in the widthwise direction of the substrate. Note that FIG. 1 illustrates an example of the layout of the pixel circuits 14, power source line 16, scanning circuit 18, and data lines 20. Accordingly, the sides of the row of the pixels 12 on which the pixel circuits 14, power source line 16, scanning circuit 18, and data lines 20 are arranged and the order in which they are arranged can be determined in accordance with each individual case.

In the light-emitting device 100 as described above, light emission of each pixel 12 is controlled by a control signal input as needed from the driving circuit corresponding to the pixel 12. An apparatus such as an electrophotographic printer can be constructed by exposing a photosensitive member with this light.

FIG. 3 illustrates a schematic cross-sectional view taken along a line A-A′ in the light-emitting device 100 illustrated in FIG. 1.

Above the substrate 10 such as a glass substrate, an undercoat layer 30 made of an inorganic insulating material such as silicon oxide (SiOₓ) or silicon nitride (SiNₓ) is formed. Above the undercoat layer 30, thin-film transistors 38 each including a channel layer 32, gate insulating film 34, and gate electrode 36 are formed. The thin-film transistor 38 is a switching element forming the driving circuit such as the pixel circuit 14 and scanning circuit 18.

Above the undercoat layer 30 on which the thin-film transistors 38 are formed, an interlayer insulating film 40 made of an inorganic insulating material such as silicon oxide or silicon nitride is formed. Above the interlayer insulating film 40, source/drain electrodes 42 electrically connected to the channel layers 32 and gate electrodes 36 of the thin-film transistors 38 through contact holes formed in the interlayer insulating film 40 and metal interconnections 44 forming the power source line 16 and data lines 20 are formed.

Above the interlayer insulating film 40 on which the source/drain electrodes 42, metal interconnections 44, and the like are formed, an interlayer insulating film 46 made of an inorganic insulating material such as silicon oxide or silicon nitride is formed. Above the interlayer insulating film 46, a lower electrode 48 electrically connected to the source/drain electrode 42 of the thin-film transistor 38 through a contact hole formed in the interlayer insulating film 46 is formed.

Above the interlayer insulating film 46 on which the lower electrode 48 is formed, a partition layer 50 made of an inorganic insulating material such as silicon oxide or silicon nitride is formed. The partition layer 50 defines a light-emitting region of an organic EL element 60 as a light-emitting element, and has an opening 52 formed in a predetermined light-emitting region on the lower electrode 48. Above the partition layer 50, an organic compound layer 54 contacting the lower electrode 48 in the opening 52, extending from inside the opening 52 onto the partition layer 50, and including a light-emitting layer is formed. As illustrated in FIG. 2, the organic compound layer 54 is continuously formed over the region where the plurality of pixels 12 is arranged.

Planarization layer 56 made of a resin material such as polyacrylic resin or polyimide is also formed above the partition layer 50. As illustrated in FIG. 2, the planarization layer 56 is selectively formed above the control circuits including the pixel circuits 14, power source line 16, scanning circuit 18, and data lines 20. In other words, the planarization layer 56 is so formed as not to extend above the pixels 12, more specifically, above the organic compound layer 54. As illustrated in FIGS. 2 and 3, spaces P are formed between the organic compound layer 54 and planarization layer 56. The space P is preferably 10 pm or more.

Above the organic compound layer 54, an upper electrode 58 is formed to extend above the partition layer 50 and planarization layer 56, thereby forming the organic EL element 60 including the lower electrode 48, organic compound layer 54, and upper electrode 58. The lower electrode 48, organic compound layer 54, and upper electrode 58 are stacked in this order from the substrate side. Note that in FIGS. 1 and 2, the pixel 12 is equivalent to the light-emitting region of the organic EL element 60, i.e., the opening 52 formed in the partition layer 50.

A passivation layer 62 made of an inorganic insulating material such as silicon nitride or silicon oxide is formed above the planarization layer 56 on which the upper electrode 58 is formed. By sealing the whole substrate 10 with the passivation layer 62 made of an inorganic material, elements such as the organic EL elements 60 formed above the substrate 10 can be shielded from an external ambient. An inorganic material such as silicon nitride is suitable as the passivation layer 62. Note that in this specification, a method of performing sealing by using the passivation layer 62 deposited above the surface of the substrate 10 will sometimes be referred to as “film sealing”.

As described above, one feature of the light-emitting device according to the present embodiment is that the partition layer 50 is made of an inorganic material.

The partition layer 50 defines the light-emitting region of the organic EL element 60, and is formed in direct contact with the organic compound layer 54. When forming the partition layer 50 by using an organic material, a photosensitive resin such as polyacrylic resin or polyimide is used. However, the material has the property that water is inherent in the material, and it is difficult to completely eliminate this water. The inventors of the present invention have found that if the partition layer 50 is formed by an organic material, therefore, water inherent in the partition layer 50 deteriorates the organic compound layer 54 and hence degrades the light emission characteristic of the organic EL element 60 in some cases. In the light-emitting device according to the present embodiment, therefore, the partition layer 50 is formed by an inorganic insulating material such as silicon nitride or silicon oxide, thereby suppressing deterioration of the light emission characteristic of the organic EL element 60 caused by water from the partition layer 50.

On the other hand, the switching elements such as thin-film transistors, the metal interconnections, and the like are arranged in the formation region of the driving circuits forming the pixel circuits 14, power source line 16, scanning circuit 18, and data lines 20, so large projections and recesses are formed above the surfaces of the switching elements, metal interconnections, and the like. When the passivation layer 62 is formed above the underlayer having large projections and recesses like these, defects may occur in the passivation layer 62 from the projections and recesses, and deteriorate the sealing performance of the passivation layer 62. The projections and recesses of the underlayer as described above can be reduced by forming the partition layer 50 having a large thickness.

If, however, the partition layer 50 made of an inorganic material is formed to have a thickness equal to that when using an organic material, the taper angle of the opening 52 becomes larger than that when using an organic material, and this makes it difficult to form the organic EL element 60 of a thin-film stack in the opening 52. Accordingly, it is difficult to form the partition layer 50 made of an inorganic material and having a thickness equal to that of a partition layer made of an organic material. From this point of view, the planarization layer 56 made of a resin material are arranged above the partition layer 50 in the light-emitting device 100 according to the present embodiment.

One function of the planarization layer 56 is to cover the projections and recesses formed by the interconnections and the switching elements above the substrate 10, such as the source/drain electrodes 42 and the metal interconnections 44, thereby reducing the projections and recesses on the surface. This function is particularly effective when performing film sealing using an inorganic material as a sealing form. This is so because if film sealing is performed in a state in which the projections and recesses remain on the surface of the substrate 10, the passivation layer 62 cannot cover these projections and recesses, and a defect may occur in the passivation layer 62 and allow the entrance of water from an external ambient.

Another function of the planarization layer 56 is to reduce a parasitic capacitance produced between the upper electrode 58 and the source/drain electrode 42, metal interconnections 44, and the like. If the spaces between the upper electrode 58, and the source/drain electrode 42 and metal interconnections 44 are narrow, the parasitic capacitances between them increase, and a defect such as a delay of an input signal occurs. The thickness of the planarization layer 56 is preferably not less than 0.5 μm. Since it is readily possible to form the planarization layer 56 having a thickness of about 0.5 μm to a few μm by using a resin, the parasitic capacitance can easily be reduced without complicating the manufacturing process.

It is possible to suitably use a photosensitive resin such as polyacrylic resin or polyimide as the planarization layer 56. As described previously, however, water is inherent in an organic material like this due to the material property, and it is difficult to completely eliminate this water. Also, if a foreign matter exists on the substrate surface during film sealing, a sealing defect sometimes occurs. Especially when a foreign matter or the like exists on the surface of the planarization layer 56 and a sealing defect occurs, water having entered from an external ambient through the defect may move and diffuse in the planarization layer 56.

In the light-emitting device according to the present embodiment as illustrated in FIGS. 2 and 3, however, the space P is formed between the organic compound layer 54 and planarization layer 56, so the organic compound layer is spaced apart from the planarization layer 56. In addition, the partition layer 50 made of an inorganic material, the upper electrode 58, and the passivation layer 62 made of an inorganic material exist between the organic compound layer 54 and planarization layer 56. Accordingly, even when water exists in the planarization layer 56 or water enters and diffuses in the planarization layer 56 through a sealing defect, the water hardly propagates to the organic compound layer 54. This makes it possible to largely suppress deterioration of the organic EL element 60 caused by water.

Note that it is not always possible to uniquely determine the space P between the organic compound layer 54 and planarization layer 56 because the space P depend on, e.g., the materials of the partition layer 50, upper electrode 58, and passivation layer 62 arranged between them as well. A minimum value of the space P is desirably set in accordance with each individual device structure as needed.

The length of the long side of the light-emitting device 100 according to the present embodiment is determined in accordance with the width of an image to be exposed. For example, this length is about 200 mm for an A4 letter size. On the other hand, the length of the short side is preferably as small as possible because the number of light-emitting devices which can be produced at once increases. For example, this length is probably a few mm or less. The length in the widthwise direction of a long substrate is more specifically 10 mm or less, and further specifically, not less than 1 mm and not more than 10 mm. Accordingly, the distance from the end of the substrate 10 to the planarization layer 56 naturally shortens, so the influence of water increases.

In the light-emitting device according to the present embodiment, however, the planarization layer 56 and organic compound layer 54 are spaced apart from each other. Even in this long light-emitting device, therefore, it is possible to effectively suppress deterioration of the organic EL element 60.

Next, a method of manufacturing the light-emitting device according to the present embodiment will be explained with reference to FIGS. 4A to 5B.

First, an undercoat layer 30 made of an inorganic insulating material such as silicon oxide or silicon nitride is formed above a substrate 10 such as a glass substrate by, e.g., CVD method.

Then, thin-film transistors 38 each including a channel layer 32, gate insulating film 34, and gate electrode 36 are formed above the undercoat layer 30 in the same manner as in a well-known, thin-film transistor manufacturing method.

Subsequently, an interlayer insulating film 40 made of an inorganic insulating material such as silicon oxide or silicon nitride is formed by, e.g., CVD method above the undercoat layer 30 on which the thin-film transistors 38 are formed.

Contact holes which are open onto the electrodes of the thin-film transistors 38 are formed in the interlayer insulating film 40 by photolithography and dry etching, and source/drain electrodes 42, metal interconnections 44, and the like connected to the thin-film transistors 38 through the contact holes are formed.

Above the interlayer insulating film 40 on which the source/drain electrodes 42 and metal interconnections 44 are formed, an interlayer insulating film 46 made of an inorganic insulating material such as silicon oxide or silicon nitride is formed by, e.g., CVD method.

A contact hole which is open onto the source/drain electrode 42 is formed in the interlayer insulating film 46 by photolithography and dry etching, and a lower electrode 48 connected to the source/drain electrode 42 through the contact hole is formed (FIG. 4A).

Above the interlayer insulating film 46 on which the lower electrode 48 is formed, a partition layer 50 made of an inorganic insulating material such as silicon oxide or silicon nitride is formed by, e.g., CVD method.

The partition layer 50 is then patterned by photolithography and dry etching, thereby forming an opening 52 which defines a light-emitting region in the partition layer 50 (FIG. 4B).

A photosensitive resin material such as polyacrylic resin or polyimide is formed above the partition layer 50 by, e.g., spin coating, and patterned by photolithography, thereby forming planarization layer 56 (FIG. 5A). By setting the film thickness of the planarization layers 56 at about 0.5 μm to a few μm, it is possible to reduce projections and recesses formed by the underlying thin-film transistors 38, source/drain electrodes 42, and metal interconnections 44.

An organic compound layer 54 is formed by, e.g., vacuum evaporation method above the lower electrode 48 exposed in the opening 52 of the partition layer 50. The organic compound layer 54 can selectively be formed in a desired region spaced apart from the planarization layers 56 by using a shadow mask. The organic compound layer 54 may include a hole transport layer, an electron transport layer, etc. as required other than a light-emitting layer containing a light-emitting material. When performing vacuum evaporation by using a shadow mask, it is also possible to place a support member on the substrate such that the support member and the mask are in contact with each other. The organic compound layer 54 can also be formed by using a deposition method which applies and dries a polymeric material.

A conductive film is deposited above the partition layer 50 on which the organic compound layer 54 and planarization layer 56 are formed and patterned, thereby forming an upper electrode 58 made of the conductive film.

Thus, an organic EL element 60 including the lower electrode 48, organic compound layer 54, and upper electrode 58 is formed (FIG. 5B).

The light-emitting device according to the present embodiment can be either a bottom emission type device which extracts light by transmitting it through the substrate 10, or a top emission type device which extracts light without transmitting it through the substrate 10. When forming the organic EL element 60 as a bottom emission type element, the lower electrode 48 is formed by a transparent electrode material such as ITO, and the upper electrode 58 is formed by a reflective electrode material such as aluminum. When forming the organic EL element 60 as a top emission type element, the lower electrode 48 is formed by the reflective electrode material, and the upper electrode 58 is formed by the transparent electrode material.

After that, a passivation layer 62 made of silicon nitride, silicon oxide or aluminum oxide is formed above the entire surface by, e.g., plasma CVD method, sputtering method or ALD method. Note that when the organic EL element 60 is a bottom emission type element, the passivation layer 62 need not be transparent. When the organic EL element 60 is a top emission type element, however, the passivation layer 62 must be transparent in order to extract light from the organic EL element 60 toward the passivation layer 62.

The passivation layer 62 is formed to the end portions of the substrate 10, and suppresses the intrusion of an external ambient containing water to the organic EL element 60. If a foreign matter exists on the substrate 10 when forming the passivation layer 62, there is the possibility that a sealing defect occurs if this foreign matter makes coverage insufficient. In the light-emitting device according to the present embodiment, however, even when a sealing defect occurs on the polarization layer 56, it is possible to sufficiently suppress water movement to the organic EL element through this defect, thereby assuring a high reliability.

In the present embodiment as described above, the partition layer is made of an inorganic material, and the planarization layer made of a resin material is formed apart from the organic compound layer. This makes it possible to prevent water from reaching the organic compound layer. Accordingly, it is possible to effectively suppress characteristic deterioration of the organic EL element caused by water, thereby improving the reliability of the light-emitting device, and prolonging the life of the device.

### Second Embodiment

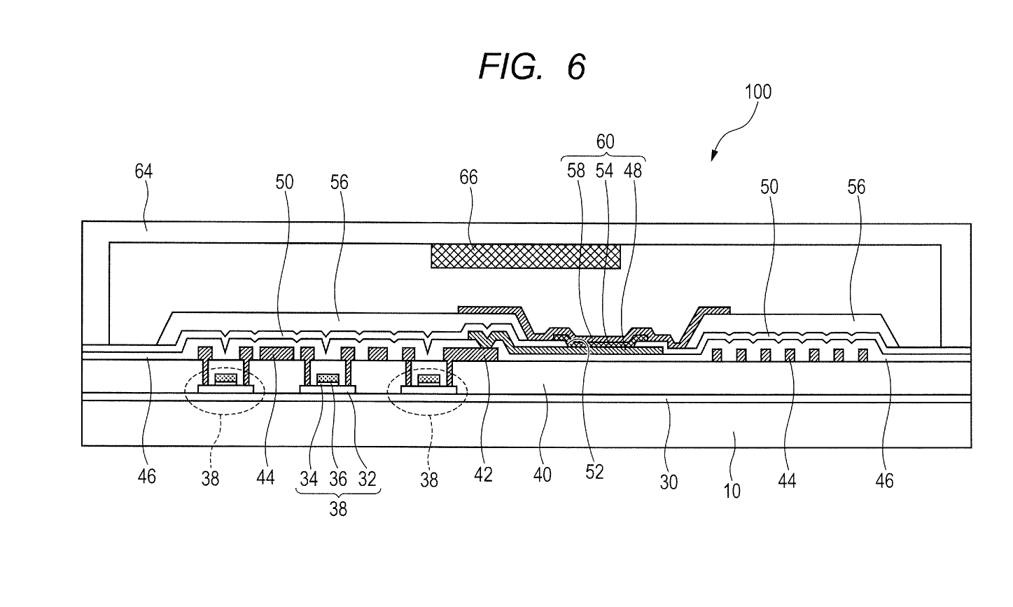

A light-emitting device and a method of manufacturing the same according to a second embodiment of the present invention will be explained with reference to FIG. 6. FIG. 6 is a schematic cross-sectional view illustrating a structure of the light-emitting device according to the present embodiment. The same reference numerals as in the light-emitting device according to the first embodiment illustrated in FIGS. 1 to 5B denote the same constituent elements, and an explanation thereof will be omitted or simplified.

As illustrated in FIG. 6, a light-emitting device 100 according to the present embodiment has a hollow sealing structure. That is, a space above a substrate 10 on which an organic EL element 60 and the like are formed is sealed by a sealing substrate 64 adhered on the substrate 10. The arrangements of control circuits, the organic EL element 60, and the like formed above the substrate 10 are the same as those of the light-emitting device according to the first embodiment.

A sealed space may include, e.g., a gelatinous material therein. In this case, it is preferable that the gelatinous material has an absorbency or an endothermy.

The light-emitting device according to the present embodiment can be formed by adhering the sealing substrate 64 having a recessed portion on the substrate 10 in a dried nitrogen ambient, after the upper electrode 58 is formed in the step illustrated in FIG. 5B. The substrate 10 and sealing substrate 64 can be adhered by, e.g., a method using flit glass or a method using a sealing agent.

Water in hollow sealing can be reduced by installing a desiccant 66 inside the sealing substrate 64 as illustrated in FIG. 6. FIG. 6 illustrates a bottom emission type organic EL element 60. In this case, light from the organic EL element 60 is extracted toward the substrate 10, so the sealing substrate 64 need not be transparent. Therefore, not only a glass material but also a metal material can be used as the sealing substrate 64.

On the other hand, when using a top emission type organic EL element 60, light from the organic EL element 60 is extracted toward the sealing substrate 64, so a transparent material such as glass is used as the sealing substrate 64. When using the desiccant 66, a transparent desiccant is used or the desiccant 66 is installed in a position where it does not block light.

In the light-emitting device according to the present embodiment, the end portion of the formation region of an organic compound layer 54 is spaced apart from the end portion of planarization layer 56, as in the light-emitting device according to the first embodiment. Accordingly, the light-emitting device according to the present embodiment can sufficiently suppress the influence of inherent water from the planarization layer 56 made of a resin material, and secure a high reliability.

In the present embodiment as described above, the partition layer is made of an inorganic material, and the planarization layer made of a resin material are formed apart from the organic compound layer. This makes it possible to prevent water from reaching the organic compound layer. Accordingly, it is possible to effectively suppress characteristic deterioration of the organic EL element caused by water, thereby improving the reliability of the light-emitting device, and prolonging the life of the device.

### Third Embodiment

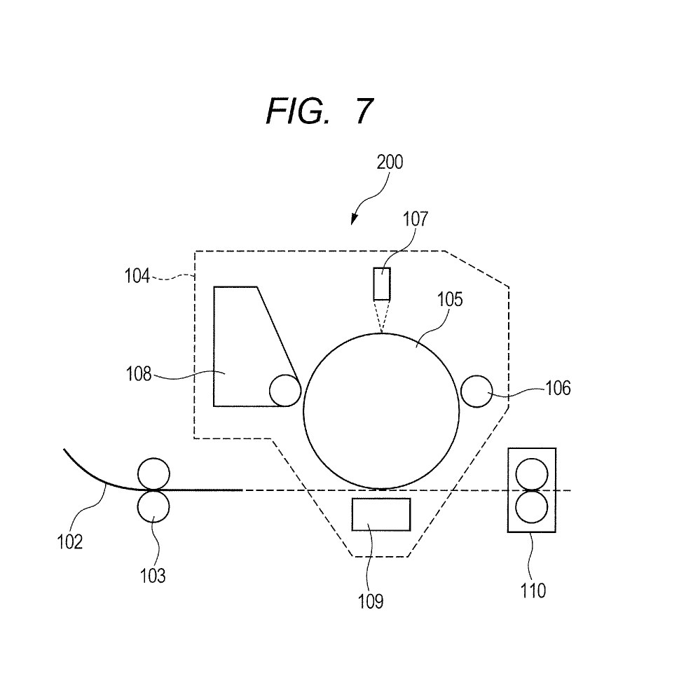

An image forming apparatus according to the second embodiment of the present invention will be explained with reference to FIG. 7. FIG. 7 is a schematic view illustrating the arrangement of the image forming apparatus according to the present embodiment.

In the present embodiment, an image forming apparatus using the light-emitting device according to the first or second embodiment as an exposure head will be explained.

First, the arrangement of the image forming apparatus according to the present embodiment will be explained with reference to FIG. 7.

As illustrated in FIG. 7, an image forming apparatus 200 according to the present embodiment includes a recording unit 104 including a photosensitive drum 105, charger 106, exposure head 107, developing device 108, and transfer device 109, conveyance rollers 103, and a fixing device 110. The light-emitting device 100 according to the first or second embodiment is used as the exposure head 107. In the exposure head 107 (the light-emitting device 100), a plurality of organic EL elements 60 are arranged along the axial direction of the photosensitive drum 105.

Next, the operation of the image forming apparatus according to the present embodiment will be explained.

In the recording unit 104, the charger 106 as a charging unit evenly charges the surface of the columnar photosensitive drum 105 as a photosensitive member.

Then, the photosensitive drum 105 is exposed with light emitted in accordance with data from the exposure head 107 as an exposure unit, thereby forming an electrostatic latent image corresponding to the exposed data on the photosensitive drum 105. This electrostatic latent image can be controlled by the exposure amount (illuminance and time) of the exposure head 107.

Subsequently, in the recording unit 104, the developing device 108 as a developing unit applies toner as a developing agent to the photosensitive drum 105 so that the toner sticks to the electrostatic latent image, and the transfer device 109 transfers the toner sticking to the electrostatic latent image to a sheet 102.

The fixing device 110 fixes the toner on the sheet 102 onto which the image data is thus transferred by the recording unit 104, and the sheet 102 is discharged. Note that the timing at which the sheet 102 is conveyed to the recording unit 104 by the conveyance rollers 103 can properly be set.

The present embodiment has been explained by taking a monochromatic image forming apparatus including one recording unit 104 as an example. However, the present invention is not limited to this, and may also be a color image forming apparatus including a plurality of recording units 104.

In the present embodiment as described above, the image forming apparatus is configured by using the light-emitting device according to the first or second embodiment, so the reliability of the image forming apparatus can be improved.

### [Modifications]

The present invention is not limited to the above-mentioned embodiments, and various modifications are possible.

For example, the driving circuits are arranged on the two sides of the row of the pixels 12 in the above-mentioned first embodiment, but the driving circuits may also be arranged on only one side of the row of the pixels 12. However, in a light-emitting device having an elongated outer shape as disclosed in the first embodiment, the organic EL element 60 is desirably spaced as apart as possible from the end portions of the substrate 10 in order to suppress deterioration of the organic EL element 60 caused by water. From this point of view, an arrangement in which the row of the pixels 12 is formed near the center of the substrate 10 and the driving circuits are arranged on the two sides of the row is more favorable.

Also, the driving circuits including the pixel circuits 14 and scanning circuit 18 are arranged on the substrate 10 in the above-mentioned first embodiment, but it is also possible to arrange only the power source line and signal lines such as the data lines 20 on the substrate 10. In this case, the driving circuits including switching elements such as the pixel circuits 14 and scanning circuit 18 can be arranged on a substrate different from the substrate 10.

In addition, the planarization layer 56 are arranged on the partition layer 50 in the above-mentioned first and second embodiments, but it is not always necessary to directly form the planarization layer 56 on the partition layer 50. In an arrangement like this, the planarization layer 56 and organic compound layer 54 can be separated by a layer formed between the partition layer 50 and planarization layer 56. To effectively prevent the entrance of water into the organic EL element 60, however, it is further favorable to arrange the planarization layer 56 so as not to overlap the organic compound layer 54 in a planar view as in the first and second embodiments.

In the second embodiment, the passivation layer 62 is not formed above the organic EL element 60. However, the passivation layer 62 may be formed also in the light-emitting device according to the second embodiment. In this case, the passivation layer 62 and the sealing substrate 64 may be spaced apart from each other.

Furthermore, the image forming apparatus disclosed in the above-mentioned third embodiment is an example of an apparatus to which the light-emitting devices according to the first and second embodiments are applicable, so the apparatus to which the light-emitting devices according to the first and second embodiments are applicable is not limited to this. The light-emitting devices according to the first and second embodiments are applicable to various apparatuses using a light source in which light-emitting elements are arranged in a row.

The present invention can prevent water from reaching the organic compound layer forming the organic EL element. This makes it possible to effectively suppress characteristic deterioration of the organic EL element caused by water, thereby improving the reliability of the light-emitting device, and prolonging the life of the device.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-163371, filed Aug. 11, 2014, and Japanese Patent Application No. 2015-129570, filed Jun. 29, 2015, which are hereby incorporated by reference herein in their entirety.

What is claimed is:

1. A light-emitting device comprising:
a plurality of pixels arranged on a long substrate along a longitudinal direction of the substrate, each pixel including a light-emitting element including a lower electrode, an organic compound layer, and an upper electrode in a stated order from the substrate;
a partition layer arranged between the lower electrode and the organic compound layer of the light-emitting element, having an opening which defines a light-emitting region of the light-emitting element, and made of an inorganic material; and
a planarization layer arranged above the partition layer spaced from the organic compound layer, and made of a resin material.

2. The light-emitting device according to claim 1, wherein
a pixel circuit configured to drive the plurality of pixels is arranged above the substrate; and
the planarization layer is arranged above the pixel circuit.

3. The light-emitting device according to claim 2, wherein
the pixel circuit is arranged adjacent to the pixels in a widthwise direction of the substrate.

4. The light emitting device according to claim 1, wherein
interconnections connected to the plurality of light-emitting elements are arranged above the substrate, and the planarization layer is arranged above the interconnections.

5. The light-emitting device according to claim 4, wherein
the interconnections are arranged adjacent to the pixels in a widthwise direction of the substrate.

6. The light-emitting device according to claim 3, wherein
interconnections connected to the plurality of light-emitting elements are arranged above the substrate,
the planarization layer is arranged above the interconnections, and
the pixel circuit, the pixels, and the interconnections are arranged in an stated order in a widthwise direction of the substrate.

7. The light-emitting device according to claim 1, further comprising
a passivation layer configured to cover the light-emitting elements and the planarization layer.

8. The light-emitting device according to claim 1, further comprising
a sealing substrate arranged above the substrate and configured to seal a space in which the light-emitting elements are formed.

9. The light-emitting device according to claim 7, further comprising
a sealing substrate configured to seal a space in which the light-emitting elements are formed,
wherein the passivation layer and the sealing substrate are spaced apart from each other.

10. The light-emitting device according to claim 8, further comprising
a desiccant in the sealed space.

11. An image forming apparatus comprising:
a photosensitive member;
an exposure unit configured to expose the photosensitive member;
a charger configured to charge the photosensitive member; and
a developing unit configured to apply a developing agent to the photosensitive member, wherein
the exposure unit includes a light-emitting device including
a plurality of pixels arranged on a long substrate along a longitudinal direction of the substrate, each pixel including a light-emitting element including a lower electrode, an organic compound layer, and an upper electrode in a stated order from the substrate;
a partition layer arranged between the lower electrode and the organic compound layer of the light-emitting element, having an opening which defines a light-emitting region of the light-emitting element, and made of an inorganic material; and
a planarization layer arranged above the partition layer spaced from the organic compound layer, and made of a resin material, and
the plurality of light-emitting elements are arranged along an axial direction of the photosensitive member.

12. An image forming apparatus comprising:
a photosensitive member;
an exposure unit configured to expose the photosensitive member;
a charger configured to charge the photosensitive member; and
a developing unit configured to apply a developing agent to the photosensitive member, wherein
the exposure unit includes a light-emitting device including
a plurality of pixels arranged on a long substrate along a longitudinal direction of the substrate, each pixel including a light-emitting element including a lower electrode, an organic compound layer, and an upper electrode in a stated order from the substrate;
a partition layer arranged between the lower electrode and the organic compound layer of the light-emitting element, having an opening which defines a light-emitting region of the light-emitting element, and made of an inorganic material; and
a planarization layer arranged above the partition layer spaced from the organic compound layer, and made of a resin material, wherein
a pixel circuit configured to drive the plurality of pixels is arranged above the substrate,
the planarization layer is arranged above the pixel circuit,
the pixel circuit is arranged adjacent to the pixels in a widthwise direction of the substrate,
interconnections connected to the plurality of light-emitting elements are arranged above the substrate,
the planarization layer is arranged above the interconnections, and
the pixel circuit, the pixels, and the interconnections are arranged in an stated order in a widthwise direction of the substrate, and
the plurality of light-emitting elements are arranged along a axial direction of the photosensitive member.
